(19) United States
(12) Patent Application Publication
(10) Pub. No.: US 2009/0146697 A1
(43) Pub. Date: Jun. 11, 2009

(54) CIRCUIT FOR BUFFERING HAVING A COUPLER

(76) Inventor: Jong Chern LEE, Chungcheongbuk-do (KR)

Correspondence Address: LADAS & PARRY LLP, 224 SOUTH MICHIGAN AVENUE, SUITE 1600, CHICAGO, IL, 60604, US

(21) Appl. No.: 12/137,127

(22) Filed: Jun. 11, 2008

(30) Foreign Application Priority Data
Dec. 7, 2007 (KR) 10-2007-0126635

(51) Int. Cl. H03K 3/00

(52) U.S. Cl. 327/108

(57) ABSTRACT

The buffer circuit includes a differential amplifier differentially amplifying a reference node corresponding to a reference voltage and an input node corresponding to the input signal by sensing a potential difference of the reference voltage and the input signal. A coupling unit couples the input signal to the reference node, making it possible to improve the operating speed of the buffer circuit and operate normally when a level of the input signal or the reference voltage becomes low.

### CROSS-REFERENCE TO RELATED APPLICATIONS

The present application claims priority to Korean patent application number 10-2007-0126635 filed on Dec. 7, 2007, which is incorporated herein by reference in its entirety.

### BACKGROUND OF THE INVENTION

The present invention relates to a semiconductor device, and more particularly to a buffer circuit buffering an input signal.

In general, a semiconductor device comprises a buffer circuit receives external signals such as a data, an address, a command, etc., and converts the external signals into signals that are suitable for an internal logic.

A conventional buffer circuit includes a differential amplifier sensing and amplifying a potential difference between a reference voltage VREF and an input signal IN, as shown in FIG. 1.

Specifically, two PMOS transistors P1, P2 are formed in a current mirror structure to supply the same current to two nodes ND1_OLD and ND2_OLD and to differentially amplify the two nodes ND1_OLD and ND2_OLD according to of the potential difference of the reference voltage VREF, which is received by the NMOS transistor N1, and the input signal IN, which is received by the NMOS transistor N2. The potential of the amplified node ND1_OLD is outputted as an output signal OUT_OLD. For reference, an NMOS transistor N3 operates as a bias current source in response to an enable signal EN.

Further, when the level of the input signal IN is low, the two PMOS transistors P1 and P2 in the current mirror structure may respond poorly to the input signal IN. In particular, when the buffer circuit is operated at a high speed, an output of the buffer circuit is delayed because the two PMOS transistors P1 and P2 respond poorly to the input signal IN, which may result in deterioration of the operating characteristics of the buffer circuit.

Also, when the level of the reference voltage VREF is low (for example, when the level of the reference voltage VREF is in the vicinity of the threshold voltage levels of the NMOS transistors N1 and N2), the NMOS transistors N1 and N2 may normally be turned-on. In this case, the NMOS transistors N1 and N2 limit a flowing current, which reduces the operating speed of the buffer circuit.

### SUMMARY OF THE INVENTION

The present invention provides a normally operable buffer circuit even in a low-level input.

The present invention provides a buffer circuit with an improved operating speed.

A buffer circuit according to an embodiment of the present invention includes a differential amplifier which differentially amplifies a reference node corresponding to a reference voltage and an input node corresponding to an input signal by sensing a potential difference of the reference voltage and the input signal, and a coupling unit coupling the input signal to the reference node.

The coupler preferably controls the potential of the reference node with the input signal. In particular, the coupler preferably controls an amount of current of the reference node corresponding to a state change in the input signal. Also, the coupler preferably includes at least one capacitor coupled between an input terminal receiving the input signal and the reference node.

The differential amplifier preferably includes an active load providing the same current to the reference node and the input node, and controlling an amount of the current according to the state of the reference node; a differential pair differentially amplifying the reference node and the input node corresponding to the potential difference of the reference voltage and the input signal, and outputting a signal corresponding to the potential of the input node; and a bias current source setting an enablement and an operating time point for the amplification.

In the configuration, the coupler preferably controls an ability of the active load to provide the current corresponding to the state change in the input signal.

The active load includes the two transistors in a current mirror structure controlling the current flowing from a power supply to the reference node and the input node according to the potential of the reference node, and the coupler preferably controls the ability of the two transistors to supply the current with the input signal.

There is provided a buffer circuit according to another embodiment of the present invention that includes a differential amplifier sensing and amplifying a potential difference between a reference voltage and an input signal, and a coupler providing the input signal as feedback to the differential amplifier to control a bias for the amplification.

According to this embodiment, the coupler preferably provides the input signal as feedback to the differential amplifier to control the bias when a state of the input signal is changed.

The differential amplifier preferably includes an active load providing the same current to a reference node corresponding to the reference voltage and an input node corresponding to the input signal, and controlling an amount of the current according to the state of the reference node; a differential pair differentially amplifying the reference node and the input node corresponding to the potential difference of the reference voltage and the input signal, and outputting a signal corresponding to the potential of the input node; and a bias current source setting an enablement and an operating time point for the amplification.

In the configuration, the coupler preferably controls the amount of the current of the reference node which determines the bias corresponding to the state change in the input signal, and in particular, the coupler preferably includes at least one capacitor coupled between an input terminal receiving the input signal and the reference node. Also, the coupler preferably controls the bias by controlling the ability of the active load to provide the current corresponding to the state change in the input signal.

The active load includes the two transistors in a current mirror structure controlling the current flowing from a power supply to the reference node and the input node according to the potential of the reference node, and the coupler preferably controls the ability of the transistor to provide the current corresponding to the two transistors with the input signal.

The present invention has an effect that the buffer circuit can normally be operated by supplementing the current of the reference node corresponding to the reference voltage with the input signal even when the level of the input signal or the reference voltage is low.

The present invention has an effect that the operating speed of the buffer circuit can be improved by controlling the bias for the differential amplification operation through the feedback of the input signal.

### BRIEF DESCRIPTION OF THE DRAWINGS

FIG. 1 is a circuit diagram showing a conventional buffer circuit.

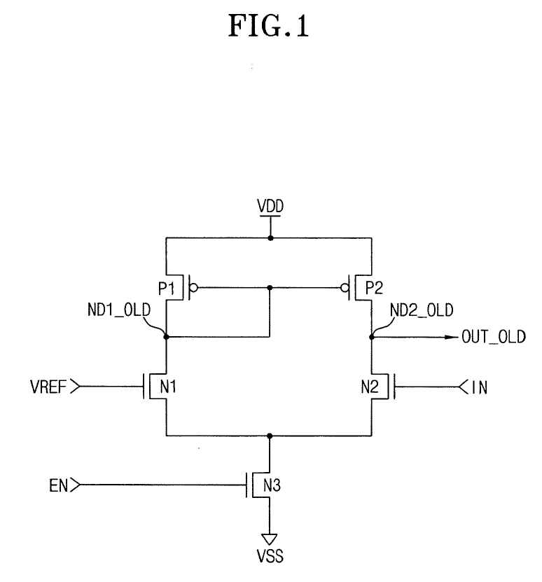

FIG. 2 is a circuit diagram showing a buffer circuit according to the present invention.

FIG. 3 is a circuit diagram showing one example a detailed configuration of a coupler 22 of FIG. 2.

FIG. 4 is a waveform diagram for explaining the operation of the buffer circuit according to the present invention by comparing it with the operation of the conventional buffer circuit.

### DESCRIPTION OF SPECIFIC EMBODIMENTS

Hereinafter, preferred embodiments of the present invention will be described in detail with reference to the accompanying drawings.

The present invention discloses a buffer circuit having a coupler controlling a bias for a differential amplification by coupling an input signal to a reference node corresponding to a reference voltage.

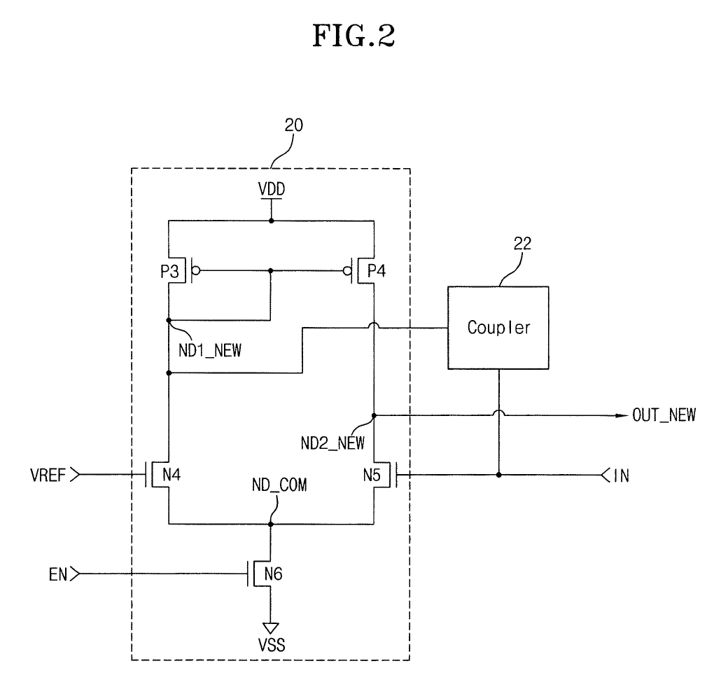

Specifically, the buffer circuit according to the present invention comprises a differential amplifier 20 sensing and amplifying a potential difference of a reference voltage VREF and an input signal IN and a coupler 22 coupling the input signal IN to a reference node ND1_NEW corresponding to the reference voltage VREW, as shown in FIG. 2.

The differential amplifier 20 differentially amplifies the reference node ND1_NEW and an input node ND2_NEW, and outputs an output signal OUT_NEW that corresponds to the potential of the amplified input node ND2_NEW. The reference node ND1_NEW corresponds to the reference voltage VREF by sensing the potential difference of the reference voltage VREF and the input signal IN. The input node ND2_NEW corresponds to the input signal IN.

An embodiment of such a differential amplifier may include an active load, a differential pair, and a bias current source.

The active load is configured to provide the same current to both the reference node ND1_NEW and the input node ND2_NEW, and to control the current according to the state of the reference node ND1_NEW. The above example may include a PMOS transistor P3 that is connected between a power supply voltage terminal VDD and the reference node ND1_NEW and a PMOS transistor P4 that is connected between the power supply voltage terminal VDD and the input node ND2_NEW. The gates of the two PMOS transistors P3 and P4 may be commonly connected to the reference node ND1_NEW.

The differential pair is configured to differentially amplify the reference node ND1_NEW and the input node ND2_NEW, corresponding to the potential difference of the reference voltage VREF and the input signal IN, and outputs the output signal OUT_NEW, corresponding to the potential of the input node ND2_NEW. The above example may include an NMOS transistor N4 connected between the reference node ND1_NEW and a common node ND_COM having a gate that receives the reference voltage VREF, and an NMOS transistor N5 connected between the input node ND2_NEW and the common node ND_COM having a gate that receives the input signal IN.

Further, the bias current source receives an enable signal EN and sets an enablement and an operating time point for the amplification according to the enable signal EN. The above example may include an NMOS transistor N6 connected between the common node ND_COM and a ground voltage terminal VSS having a gate that receives the enable signal EN.

The coupler 22 is configured to control the bias of the differential amplifier 20 by coupling the input signal IN to the reference node ND1_NEW, which corresponds to the reference voltage VREF. In other words, the coupler 22 may control the potential of the reference node ND1_NEW by providing the input signal IN to the reference node ND1_NEW of the differential amplifier 20 as a feedback signal, and the coupler 22 may also control the amount of current of the reference node ND1_NEW corresponding to the state change in the input signal IN.

Further, the coupler 22 may be configured to control the ability of the active load to supply current when the differential amplifier 20 includes the active load described above.

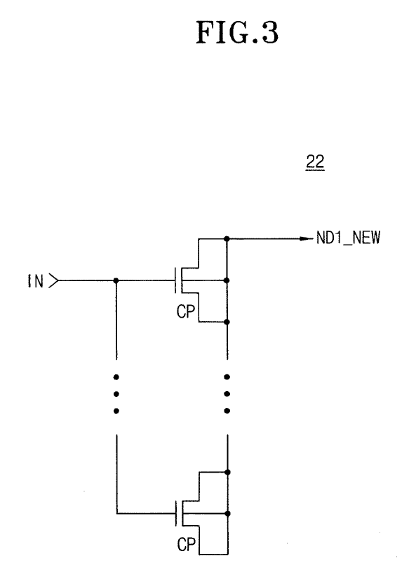

One example of such a coupler 22 includes at least one capacitor CP coupled to the input terminal receiving the input signal IN and the reference node ND1_NEW, as shown in FIG. 3.

Herein, the capacitor CP may be an NMOS transistor type capacitor having a gate that receives the input signal IN and having a source and a drain commonly connected to the reference node ND1_NEW. The capacitor CP may be any one of an NMOS transistor type capacitor, a PMOS transistor type capacitor, or any other type of capacitors.

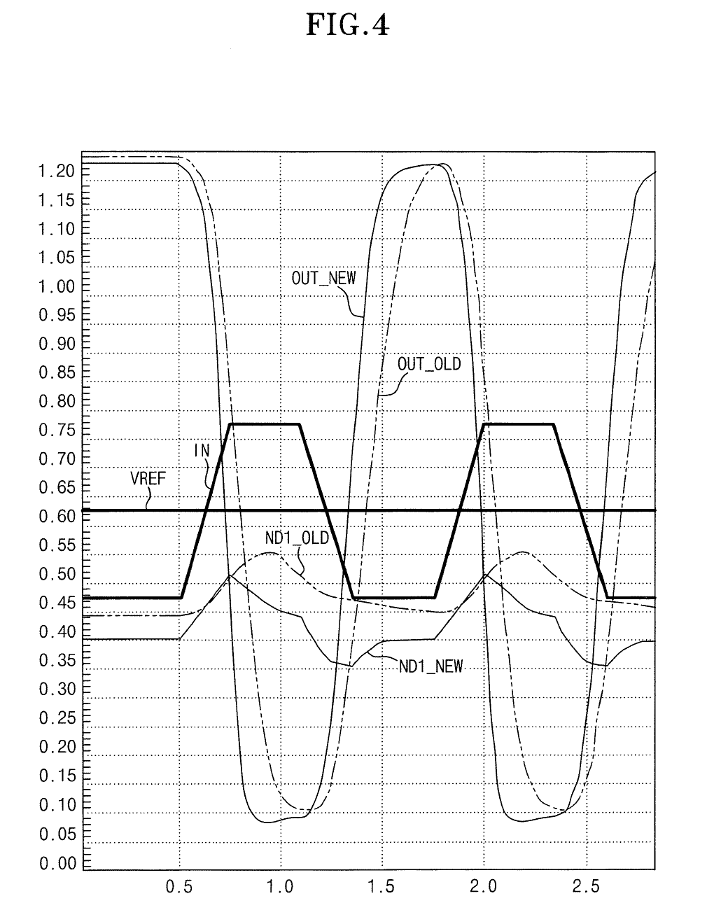

The operation of the buffer circuit according to the present invention will now be described below with reference to FIG. 4 by comparing it with the operation of the conventional buffer circuit. For reference, FIG. 4 shows the levels of the reference voltage VREF, the input signal IN, the input nodes ND1_OLD and ND1_NEW, and the output signals OUT_OLD and OUT_NEW depending on the time.

When the input signal IN is input at a lower level than the reference voltage VREF, the reference node ND1_NEW becomes a logic low level and the input node ND2_NEW becomes a logic high level due to the mutual drive of the NMOS transistors N4 and N5.

In this state, when the level of the input signal IN rises, the power that corresponds to the input signal IN is supplied to the reference node ND1_NEW through the coupler 22 and increases the amount of current flowing to the reference node ND1_NEW more rapidly than the conventional reference node ND1_OLD. As a result, the drivability of the two PMOS transistors P3 and P4 included in the differential amplifier 20 decreases, and in particular, the potential of the input node ND2_NEW rapidly decreases to the logic low level as the drivability of the PMOS transistor P4 decreases.

In other words, when the level of the input signal IN increases but is still less than the reference voltage VREF, the bias is changed depending on the supply of the power corresponding to the input signal IN to the reference node ND1_NEW through the coupler 22 so that the differential amplification operating time point is fast. As a result, the output signal OUT_NEW decreases more rapidly to the logic low level than the conventional output signal OUT_OLD.

Thereafter, when the input signal IN is maintained at a predetermined level state higher than the reference voltage VREF, the operation of the coupler 22 stops so that the power corresponding to the input signal IN is not supplied to the reference node ND1_NEW, and the reference node ND1_NEW is maintained at the logic high level and the input node ND2_NEW is maintained at the logic low level.

When the level of the input signal IN decreases, the power corresponding to the input signal IN is coupled to the reference node ND1_NEW through the coupler 22 so that the amount of current flowing to the reference node ND1_NEW is reduced more rapidly than the conventional reference node ND1_OLD. As a result, the drivability of the two PMOS transistors P3 and P4 included in the differential amplifier 20 is improved, and in particular, the potential of the input node ND2_NEW increases rapidly to the logic high level as the drivability of the PMOS transistor P4 is improved.

In other words, when the level of the input signal IN decreases in the state where the input signal IN is maintained at a predetermined level higher than the reference voltage VREF, the bias is changed depending on the coupling of the power supply corresponding to the input signal IN to the reference node ND1_NEW through the coupler 22 so that the differential amplification operating time point is fast. As a result, the output signal OUT_NEW increases to the logic high level more rapidly than the conventional output signal OUT_OLD.

As described above, the buffer circuit according to the present invention supplies the power corresponding to the input signal IN to the reference node ND1_NEW when the state of the input signal IN is changed so that the potential of the reference node ND1_NEW is changed more rapidly.

Therefore, although the level of the input signal IN or the reference voltage VREF is low, the normal operation of the buffer circuit can be performed since the normal potential of the reference node ND1_NEW is maintained.

Also, the buffer circuit according to the present invention provides the input signal IN as feedback to the reference node ND1_NEW of the differential amplifier 20 when the state of the input signal IN is changed, thereby momentarily changing the bias for the differential amplification operation.

At this time, the operating speed of the buffer circuit is improved so that the output signal OUT_NEW can be amplified to a target level quickly because the amplification operating time point of the differential amplifier 20 is fast depending on the change in the bias.

Those skilled in the art will appreciate that the specific embodiments disclosed in the foregoing description may be readily utilized as a basis for modifying or designing other embodiments for carrying out the same purposes of the present invention. Those skilled in the art will also appreciate that such equivalent embodiments do not depart from the spirit and scope of the invention as set forth in the appended claims.

What is claimed is:

1. A buffer circuit having a coupler, the buffer circuit comprising:
a differential amplifier differentially amplifying a reference node corresponding to a reference voltage and an input node corresponding to an input signal by sensing a potential difference of the reference voltage and the input signal; and
the coupler coupling the input signal to the reference node.

2. The buffer circuit as set forth in claim 1, wherein the coupler controls the potential of the reference node according to the input signal.

3. The buffer circuit as set forth in claim 2, wherein the coupler controls an amount of current of the reference node corresponding to a state change in the input signal.

4. The buffer circuit as set forth in claim 1, wherein the coupler comprises at least one capacitor coupled between an input terminal receiving the input signal and the reference node.

5. The buffer circuit as set forth in claim 1, wherein the differential amplifier comprises:
an active load providing the same current to the reference node and the input node, and controlling an amount of the current according to a state of the reference node;
a differential pair differentially amplifying the reference node and the input node corresponding to the potential difference of the reference voltage and the input signal, and outputting a signal corresponding to the potential of the input node; and
a bias current source setting an enablement and an operating time point for the amplification.

6. The buffer circuit as set forth in claim 5, wherein the coupler controls an ability of the active load to provide the current corresponding to the state change in the input signal.

7. The buffer circuit as set forth in claim 6, wherein the active load comprises two transistors in a current mirror structure controlling the current flowing from a power supply to the reference node and the input node according to the potential of the reference node, and the coupler controls the ability of the two transistors to supply the current with the input signal.

8. A buffer circuit having a coupler, the buffer circuit comprising:
a differential amplifier sensing and amplifying a potential difference between a reference voltage and an input signal; and
the coupler providing the input signal as feedback to the differential amplifier to control a bias for the amplification.

9. The buffer circuit as set forth in claim 8, wherein the coupler provides the input signal as feedback to the differential amplifier to control the bias when a state of the input signal is changed.

10. The buffer circuit as set forth in claim 8, wherein the differential amplifier comprises:
an active load providing the same current to a reference node corresponding to the reference voltage and an input voltage corresponding to the input signal, and controlling an amount of the current according to the state of the reference node;
a differential pair differentially amplifying the reference node and the input node corresponding to the potential difference of the reference voltage and the input signal, and outputting a signal corresponding to the potential of the input node; and
a bias current source setting an enablement and an operating time point for the amplification.

11. The buffer circuit as set forth in claim 10, wherein the coupler controls the amount of the current of the reference node, wherein the amount of the current of the reference node determines the bias corresponding to the state change in the input signal.

12. The buffer circuit as set forth in claim 10, wherein the coupler comprises at least one capacitor coupled between an input terminal receiving the input signal and the reference node.

13. The buffer circuit as set forth in claim 10, wherein the coupler controls the bias by controlling the ability of the active load to provide the current corresponding to the state change in the input signal.

14. The buffer circuit as set forth in claim 13, wherein the active load comprises two transistors in a current mirror structure controlling the current flowing from a power supply to the reference node and the input node according to the potential of the reference node, and the coupler controls the ability of the transistor to provide the current corresponding to the two transistors with the input signal.
